(19) United States
(12) Patent Application Publication
(10) Pub. No.: US 2020/0363146 A1
(43) Pub. Date: Nov. 19, 2020

(54) HEAT EXCHANGE APPARATUS, AND HEAT EXCHANGE METHOD THEREFOR AND VAPOUR DEPOSITION DEVICE THEREOF

(71) Applicant: SHANGHAI MICRO ELECTRONICS EQUIPMENT (GROUP) CO., LTD., Shanghai (CN)

(72) Inventors: Tengjun YANG, Shanghai (CN); Yufeng WANG, Shanghai (CN)

(73) Assignee: Shanghai Micro Electronics Equipment (Group) Co., Ltd., Shanghai (CN)

(21) Appl. No.: 16/632,279

(22) PCT Filed: Jul. 16, 2018
(86) PCT No.: PCT/CN2018/095850

§ 371 Date: Jan. 17, 2020

(30) Foreign Application Priority Data
Jul. 17, 2017 (CN) 201710582127.2

(51) Int. Cl. F28F 27/02; G05D 7/06; C23C 16/46

(52) U.S. Cl. CPC F28F 27/02; C23C 16/463; G05D 7/0652

(57) ABSTRACT

A heat exchange apparatus, heat exchange method, and vapour deposition device. The heat exchange apparatus performs cooling processing on a target object to be cooled, and has a heat exchanger, cooling water channels, water circulation channels and switchers. The cooling water channels realize heat exchange between cooling water and the heat exchanger. The water circulation channels perform temperature control on the target object to be cooled. The switchers disconnect the water circulation channels from the target object to be cooled, and realize the connection between the cooling water channels and the target object to be cooled. The heat exchange apparatus can also realize cooling with the cooling water provided by a cooling water inlet pipe when the heat exchanger fails, ensuring that the target object to be cooled, in particular a process cavity, can be subjected to effective cooling in any circumstances, to ensure normal production.

### TECHNICAL FIELD

The present invention relates to the field of semiconductor manufacture and, in particular, to a heat exchange apparatus, a heat exchange method thereof and a vapour deposition device.

### BACKGROUND

In semiconductor manufacturing processes, heat exchange apparatus are often used to cool equipment in a hot state. FIG. 1 illustrates a conventional device that accomplishes heat exchange of equipment through facility cooling water and circulating water.

The operating principle of the heat exchange apparatus as shown in FIG. 1 is that: the circulating water from a water tank 101 is pressurized by a pump 102, and then flows into the reaction chamber 107, after successively flowing through a temperature sensor 104, pressure sensor 105 and a flow meter 106, so as to cool the reaction chamber 107. After that, the circulating water carrying the absorbed heat flows into the heat exchanger 108, where heat exchange takes place with facility cooling water, and then back to the water tank 101. During this process, the facility cooling water exchanges heat with the circulating water via the heat exchanger 108. Specifically, the facility cooling water flows into the cooling water inlet pipe 110, passes through the heat exchanger 108 and flows out of the cooling water outlet pipe 111. An enhanced heat exchange efficiency between the circulating water and facility cooling water can be achieved when a bypass ball valve 103 is open. The temperature sensor 104 is used to measure a temperature of the circulating water, while the pressure sensor 105 is configured to measure a pressure of the circulating water. The flow meter 106 is adapted to measure a flow rate of the circulating water, and a two-way control valve 109 is disposed in the cooling water inlet pipe 110 in order to adjust a flow rate of the facility cooling water. This design allows intelligent temperature control of the reaction chamber 107.

However, the inventors have found that once the heat exchange apparatus becomes malfunctioning, the circulating water would stop flowing, failing to transfer heat of the reaction chamber 107. As a result, the reaction chamber 107 will be heated up (e.g., up to 1100° C.) and may be therefore damaged.

### SUMMARY

An object of the present application is to provide a heat exchange apparatus, a heat exchange method and a vapour deposition device, in order to overcome the problem of damages of the object to be cooled due to the failure of heat transfer when a conventional heat exchange apparatus malfunctions and cannot work.

To this end, the present application provides a heat exchange apparatus configured to cool an object to be cooled, which comprises a heat exchanger, a cooling water channel, a circulating water channel and a switcher. The cooling water channel is configured for heat exchange between cooling water and the heat exchanger, and the circulating water channel is configured to control a temperature of the object to be cooled. The switcher is configured to disconnect the circulating water channel from the object to be cooled while connecting the cooling water channel to the object to be cooled.

Optionally, the cooling water channel comprises a cooling water inlet pipe and a cooling water outlet pipe that are connected to the heat exchanger, wherein the circulating water channel comprises a circulating water outlet pipe and a circulating water return pipe, and wherein the heat exchanger, the circulating water outlet pipe, the object to be cooled and the circulating water return pipe are connected in series to form a loop.

Optionally, the switcher comprises a first switcher and a second switcher, wherein the first switcher is disposed between the cooling water inlet pipe and the circulating water outlet pipe and configured to disconnect part of the circulating water outlet pipe and the object to be cooled while connecting the cooling water inlet pipe and the object to be cooled, and wherein the second switcher is disposed between the cooling water outlet pipe and the circulating water return pipe and configured to disconnect the cooling water outlet pipe and the heat exchanger while connecting the cooling water outlet pipe and the object to be cooled.

Optionally, each of the first switcher and the second switcher is a three-way valve.

Optionally, the circulating water return pipe comprises a first circulating water return pipe and a second circulating water return pipe, wherein the circulating water outlet pipe comprises a first circulating water outlet pipe and a second circulating water outlet pipe,

wherein a first end of the first circulating water outlet pipe is connected to the heat exchanger with a second end of the first circulating water outlet pipe being connected to the first switcher, wherein a first end of the second circulating water outlet pipe is connected to the first switcher with a second end of the second circulating water outlet pipe being connected to the object, and wherein the cooling water inlet pipe is connected to the first switcher via a first by-pass,

wherein a first end of the first circulating water return pipe is connected to the second switcher with a second end of the first circulating water return pipe being connected to the object to be cooled, wherein a first end of the second circulating water out and inlet pipe is connected to the heat exchanger with a second end of the second circulating water out and inlet pipe being connected to the second switcher, and wherein the cooling water outlet pipe is connected to the second switcher via a second by-pass.

Optionally, the three-way valve is a pneumatically-controlled three-way valve.

Optionally, the pneumatically-controlled three-way valve is provided with a delivery passageway for allowing passage of compressed air, and arrangements of a pressure gauge and a pressure alarm into the delivery passageway are provided, wherein the pressure gauge is configured to measure a pressure of the compressed air and a pressure alarm is configured to give an alarm once the pressure of the compressed air drops below a preset value.

Optionally, the first switcher comprises a first normally closed solenoid valve and a first normally open solenoid valve, wherein the second switcher comprises a second normally closed solenoid valve and a second normally open solenoid valve.

Optionally, the cooling water inlet pipe is connected to the circulating water outlet pipe via a first by-pass, and the first normally open solenoid valve is disposed in the first by-pass with the circulating water outlet pipe being provided with the first normally closed solenoid valve, and wherein the cooling water outlet pipe is connected to the circulating water return pipe via a second by-pass, and the second normally open solenoid valve is disposed in the second by-pass with the circulating water return pipe being provided with the second normally closed solenoid valve.

Optionally, the cooling water inlet pipe is connected to the circulating water outlet pipe via a first by-pass, and the first normally closed solenoid valve is disposed in the first by-pass with the circulating water outlet pipe being provided with the first normally open solenoid valve, and wherein the cooling water outlet pipe is connected to the circulating water return pipe via a second by-pass, and the second normally closed solenoid valve is disposed in the second by-pass, with the circulating water return pipe being provided with the second normally open solenoid valve.

Optionally, the heat exchange apparatus further comprises a controller for controlling a power on or power off of the first and second normally closed solenoid valves and the first and second normally open solenoid valves.

Optionally, one or more of a temperature sensor, a pressure sensor and a flow meter may be disposed in the circulating water channel.

Optionally, the object to be cooled may be a process chamber.

The present application also provides a heat exchange method of the heat exchange apparatus, which comprises:

disconnecting, by the first switcher, part of the circulating water outlet pipe and the object to be cooled while connecting the cooling water inlet pipe and the object to be cooled, so that cooling water flows into the object to be cooled after successively flowing through the cooling water inlet pipe and part of the circulating water outlet pipe; and

disconnecting, by the second switcher, the heat exchanger and the object to be cooled while connecting the cooling water outlet pipe and the object to be cooled, so that the cooling water flowing out of the object to be cooled successively flows through the circulating water return pipe and the cooling water outlet pipe to accomplish heat exchange between the cooling water and the object to be cooled.

Optionally, each of the first switcher and the second switcher is a three-way valve, wherein connecting each of the cooling water inlet pipe and cooling water outlet pipe to the object to be cooled comprises:

controlling, by a pneumatic actuating unit, the first switcher to disconnect the circulating water channel and the object to be cooled while connecting the cooling water inlet pipe and the object to be cooled; and

controlling, by the pneumatic actuating unit, the second switcher to disconnect the heat exchanger and the object to be cooled while connecting the cooling water outlet pipe and the object to be cooled.

Optionally, the first switcher comprises a first normally closed solenoid valve and a first normally open solenoid valve, wherein the second switcher comprises a second normally closed solenoid valve and a second normally open solenoid valve, and wherein connecting each of the cooling water inlet pipe and cooling water outlet pipe to the object to be cooled comprises:

closing the first normally open solenoid valve and the second normally open solenoid valve to connect the object to be cooled to each of the cooling water inlet pipe and the cooling water outlet pipe; and

opening the first normally closed solenoid valve and the second normally closed solenoid valve to disconnect the object to be cooled from each of the circulating water channel and heat exchanger.

The present application also provides a vapour deposition device comprising the heat exchange apparatus, wherein the heat exchange apparatus is configured to control a temperature of the vapour deposition device.

In summary, the present application provides a heat exchange apparatus, a heat exchange method and a chemical vapour deposition device. The heat exchange apparatus includes a heat exchanger, a cooling water channel, a circulating water channel and a switcher. The cooling water channel is configured to exchange heat with the circulating water channel at the heat exchanger, and the circulating water channel is configured to control a temperature of the object to be cooled. The switcher is configured to disconnect the circulating water channel and the object to be cooled while connecting the cooling water channel and the object to be cooled.

In such a case, when the heat exchange apparatus malfunctions, the switcher disconnect the circulating water channel and the object to be cooled while connecting the cooling water channel and the object to be cooled so that the object to be cooled is supplied with the cooling water via the cooling water channel for cooling, enabling to ensure an effective cooling of the object to be cooled, in particular, the reaction chamber for chemical/physical vapour deposition at any situation, and thus ensure a smooth production.

### BRIEF DESCRIPTION OF THE DRAWINGS

FIG. 1 schematically illustrates connection of a conventional heat exchange apparatus with a reaction chamber.

FIG. 2 schematically illustrates connection of a heat exchange apparatus according to embodiment 1 of the present application with a reaction chamber.

FIG. 3 schematically illustrates the heat exchange apparatus of FIG. 2 operating in a malfunctioning state.

FIG. 4a schematically illustrates the switch between the first switcher and the second switcher of the heat exchange apparatus of FIG. 2 operating in a normal state.

FIG. 4b schematically illustrates the switch between the first switcher and the second switcher of the heat exchange apparatus of FIG. 2 operating in a malfunctioning state.

FIG. 5 schematically illustrates connection of a heat exchange apparatus according to embodiment 2 of the present application with a reaction chamber.

FIG. 6 schematically illustrates the heat exchange apparatus of FIG. 5 operating in a malfunctioning state.

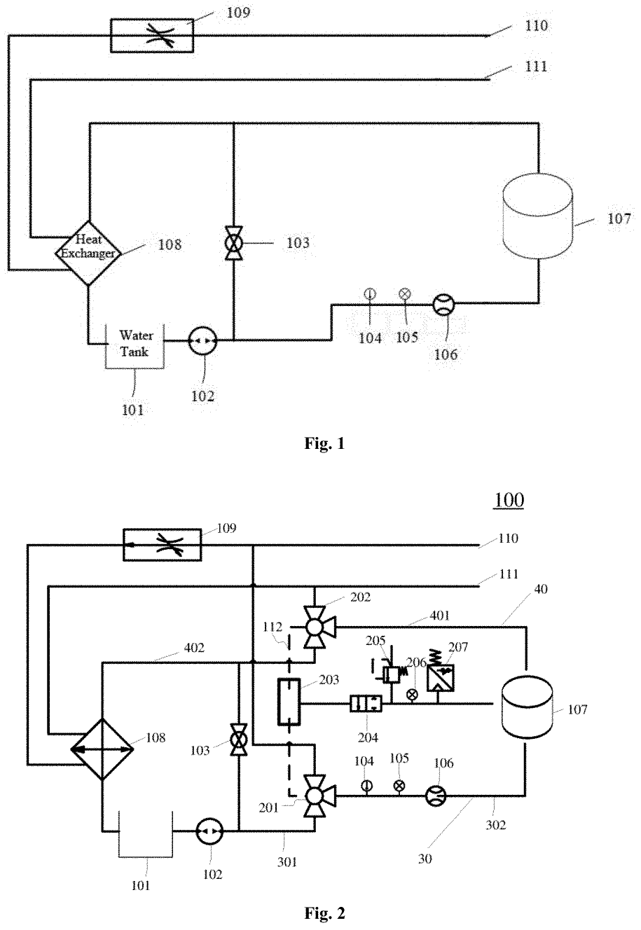

In the figures,

101—water tank; 102—pump; 103—bypass ball valve; 104—temperature sensor; 105—pressure sensor; 106—flow meter; 107—reaction chamber; 108—heat exchanger; 109—two-way control valve; 110—cooling water inlet pipe; 111—cooling water outlet pipe;

112—gas passageway; 201—first switcher; 202—second switcher; 203—pneumatic actuating unit; 204—solenoid valve; 205—pressure regulating valve; 206—pressure gauge; 207—pressure alarm;

30—circulating water outlet pipe; 301—first circulating water outlet pipe; 302—second circulating water outlet pipe; 40—circulating water return pipe; 401—first circulating water return pipe; and 402—second circulating water return pipe.

### DETAILED DESCRIPTION

Specific embodiments of the present application will be described in greater detail below with reference to the accompanying drawings. Features and advantages of the invention will be more apparent from the following detailed description, and from the appended claims. It should be noted that the accompanying drawings are provided in a very simplified form not necessarily presented to precise scale, with the only intention to facilitate convenience and clarity in explaining the embodiments.

In the following description, for the purpose of simple illustration, the structure and operation of the heat exchange apparatus of the present application will be detailed taking the heat exchange apparatus used in a reaction chamber of a chemical vapour deposition device as an example. However, the objects to be cooled in the present application are included, but are not limited to, the reaction chamber of the chemical vapour deposition device.

### Embodiment 1

FIG. 2 is a structural schematic of a heat exchange apparatus 100 according to embodiment of the present application, which is connected to a reaction chamber 107. As shown in FIG. 2, the heat exchange apparatus 100 includes a heat exchanger 108, a water tank 101, a cooling water inlet pipe 110, a cooling water outlet pipe 111, a circulating water outlet pipe 30, a circulating water return pipe 40, a first switcher 201 and a second switcher 202. The cooling water inlet pipe 110 and cooling water outlet pipe 111 are both connected to the heat exchanger 108, and cooling water is designed to flow through the cooling water inlet pipe 110 into the heat exchanger 108, where it experiences heat exchange, and flows out through the cooling water outlet pipe 111. The heat exchanger 108, water tank 101, circulating water outlet pipe 30, reaction chamber 107 and circulating water return pipe 40 are sequentially connected in series to form a loop. The cooling water inlet pipe 110 and the cooling water outlet pipe 111 together make up a cooling water channel, while the circulating water outlet pipe 30 and the circulating water return pipe 40 constitute a circulating water channel.

Each of the first switcher 201 and the second switcher 202 is a three-way valve. The three-way valve performs switching actions under the control of a pneumatic actuating unit 203 which may use compressed air supplied from an external source to control the first switcher 201 and the second switcher 202. In other words, the three-way valve may be a pneumatically-controlled three-way valve, and the first switcher 201 and the second switcher 202 may be driven by the same pneumatic actuating unit 203. In this case, the first switcher 201 and the second switcher 202 function as a dual pneumatically-controlled three-way valve. Optionally, the pneumatic actuating unit 203 includes an intake pipe. The intake pipe is provided therein with a solenoid valve 204 for controlling the open or closure of the intake pipe. The intake pipe may be additionally provided therein with a pressure regulating valve 205 for adjusting a pressure of the compressed air to a desired value. In such an arrangement, the pressure of the compressed air is adjustable and the control of the three-way valve becomes more flexible. Preferably, the intake pipe may be further provided therein with a pressure gauge 206, which can detect the pressure of the compressed gas in real time, and work with the pressure regulating valve 205 to accurately control the pressure of the compressed gas. Furthermore, the intake pipe may be provided therein with a pressure alarm 207, which can raise an alarm when the pressure of the compressed air falls below a preset value in order to provide an indication to the operator, making the operation of the heat exchange apparatus 100 more user-friendly.

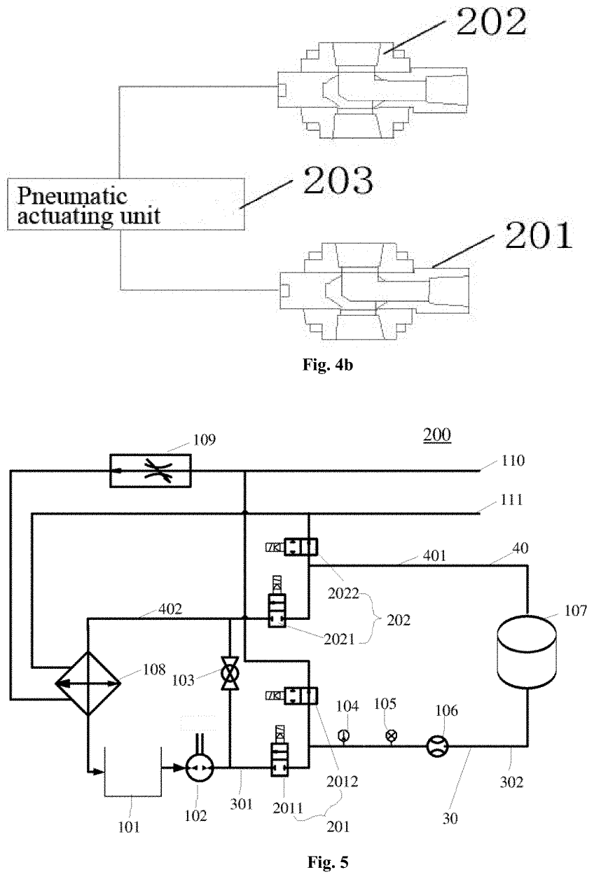

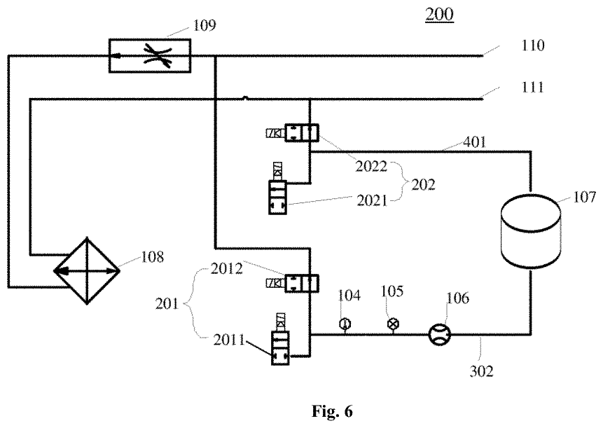

As shown in FIG. 4a, in normal operation of the heat exchange apparatus 100, the first switcher 201 connects the water tank 101 to the reaction chamber 107 via the circulating water outlet pipe 30, simultaneously with the second switcher 202 connecting the heat exchanger 108 to the reaction chamber 107 via the circulating water return pipe 40. Then, facility cooling water is allowed to flow from the cooling water inlet pipe 110 into the heat exchanger 108, where it exchanges heat with circulating water entering into the heat exchanger 108. The facility cooling water is less stable in temperature than the circulating water. Subsequent to the heat exchange, the cooling water flows out from the heat exchanger 108 and flows out through the cooling water outlet pipe 111, while the circulating water flows into the water tank 101 and again flows into the reaction chamber 107 for heat exchange via the circulating water outlet pipe 30. Moreover, the circulating water flowing into the reaction chamber 107 and having experienced the heat exchange process flows back to the heat exchanger 108 via the circulating water return pipe 40. In this way, the reaction chamber 107 can be cyclically cooled by the supplied circulating water.

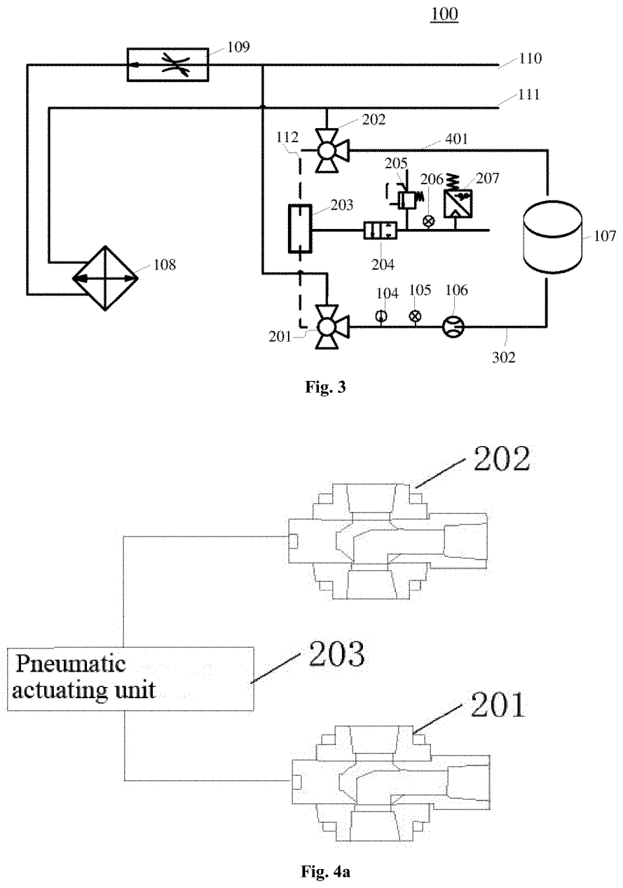

FIG. 3 schematically illustrates the heat exchange apparatus 100 of FIG. 2 operating in a malfunctioning state. Referring to FIG. 3, in combination with FIG. 4b, in the malfunctioning state of the heat exchange apparatus 100, the first switcher 201 disconnects the water tank 101 from the reaction chamber 107 while connecting the cooling water inlet pipe 110 to the reaction chamber 107. At the same time, the second switcher 202 disconnects the heat exchanger 108 from the reaction chamber 107 while connecting the cooling water outlet pipe 111 to the reaction chamber 107. Through changing to the above connection manner, the facility cooling water is allowed to directly flow into the reaction chamber 107 via the cooling water inlet pipe 110 and circulating water outlet pipe 30. In addition, after undergoing heat exchange in the reaction chamber 107, the cooling water successively flows through the circulating water return pipe 40 and cooling water outlet pipe 111 after flowing out from the reaction chamber 107. As a result, cooling of the reaction chamber 107 by the facility cooling water can be achieved.

According to this embodiment, the circulating water outlet pipe 30 includes a first circulating water outlet pipe 301 and a second circulating water outlet pipe 302. One end of the first circulating water outlet pipe 301 is connected to the water tank 101, and the other end of the first circulating water outlet pipe 301 is connected to the first switcher 201. One end of the second circulating water outlet pipe 302 is connected to the first switcher 201, and the other end of the second circulating water outlet pipe 302 is connected to the reaction chamber 107. Therefore, in the malfunctioning state of the heat exchange apparatus 100, the first switcher 201 disconnects the first circulating water outlet pipe 301 from the water tank 101 while connecting the second circulating water outlet pipe 302 to the cooling water inlet pipe 110. Specifically, the cooling water inlet pipe 110 is connected to the second circulating water outlet pipe 302 via a first by-pass.

According to this embodiment, the circulating water return pipe 40 includes a first circulating water return pipe 401 and a second circulating water return pipe 402. One end of the second circulating water return pipe 402 is connected to the heat exchanger 108, and the other end of the second circulating water return pipe 402 is connected to the second switcher 202. One end of the first circulating water return pipe 401 is connected to the second switcher 202, and the other end of the first circulating water return pipe 401 is connected to the reaction chamber 107. Therefore, in the malfunctioning state of the heat exchange apparatus 100, the second switcher 202 disconnects the second circulating water return pipe 402 from the heat exchanger 108 while connecting the first circulating water return pipe 401 to the cooling water outlet pipe 111. Specifically, the cooling water outlet pipe 111 is connected to the first circulating water return pipe 401 via a second by-pass.

To sum up, when the heat exchange apparatus 100 operates in the malfunctioning state, the facility cooling water from the cooling water inlet pipe 110 flows successively through the first by-pass and the second circulating water outlet pipe 302 into the reaction chamber 107, thus enabling to cool the reaction chamber 107. After that, the facility cooling water flowing out from the reaction chamber 107 passes through the first circulating water return pipe 401, the second by-pass and the cooling water outlet pipe 111. Thus, cooling of the reaction chamber 107 is able to be achieved.

In the above embodiment, one or more of a temperature sensor 104, a pressure sensor 105 and a flow meter 106 may be disposed in one or more of the circulating water return pipe 40 and circulating water outlet pipe 30 in order to monitor the operation of the heat exchange apparatus 100. The pneumatic actuating unit 203 supplies air to the first switcher 201 and the second switcher 202 through gas passageway 112 so as to control switching of the first switcher 201 and the second switcher 202.

### Embodiment 2

FIG. 5 is a structural schematic of a heat exchange apparatus 200 according to embodiment 2 of the present application, which is connected to a reaction chamber 107. As shown in FIG. 5, the heat exchange apparatus 200 includes a heat exchanger 108, a water tank 101, a cooling water inlet pipe 110, a cooling water outlet pipe 111, a circulating water outlet pipe 30, a circulating water return pipe 40, a first switcher 201 and a second switcher 202. The cooling water inlet pipe 110 and cooling water outlet pipe 111 are both connected to the heat exchanger 108, and cooling water is designed to flow through the cooling water inlet pipe 110 into the heat exchanger 108, where it undergoes a heat exchange process, and then flows out through the cooling water outlet pipe 111. The heat exchanger 108, water tank 101, circulating water outlet pipe 30, reaction chamber 107 and circulating water return pipe 40 are sequentially connected in series to form a loop.

This embodiment differs from Embodiment 1 in that: the first switcher 201 according to this embodiment includes one normally closed solenoid valve 2011 and one normally open solenoid valve 2012, and the second switcher 202 accordingly includes one normally closed solenoid valve 2021 and one normally open solenoid valve 2022.

Each of the normally closed solenoid valves 2011, 2021 and normally open solenoid valves 2012, 2022 may be controlled by an electric circuit. In normal operation of the heat exchange apparatus 200, the normally closed solenoid valves 2021, 2011 are powered on and open, while the normally open solenoid valves 2022, 2012 are powered on and closed. At this time, the cooling water inlet pipe 110 is disconnected from the reaction chamber 107, and the heat exchanger 108 is connected to the reaction chamber 107. Moreover, the cooling water outlet pipe 111 is disconnected from the reaction chamber 107, and the water tank 101 is connected to the reaction chamber 107. In this case, heat exchange process of the heat exchange apparatus 200 is carried out in the same way as that of the heat exchange apparatus 100 of Embodiment 1 operating in the normal state and is thus not described in detail again.

In a malfunctioning state of the heat exchange apparatus 200, all the normally closed solenoid valves 2021, 2011 and normally open solenoid valves 2012, 2022 are powered off simultaneously, so that the normally closed solenoid valves 2021, 2011 are closed while the normally open solenoid valves 2012, 2022 are open. At this time, the normally closed solenoid valve 2011 of the first switcher 201 is opened to disconnect the first circulating water outlet pipe 301 and the water tank 101, and the normally open solenoid valve 2012 of the first switcher 201 is opened to connect the cooling water inlet pipe 110 and the second circulating water outlet pipe 302. The normally closed solenoid valve 2021 of the second switcher 202 is opened to disconnect the second circulating water return pipe 402 and the heat exchanger 108, and the normally open solenoid valve 2022 of the second switcher 202 is opened to connect the cooling water outlet pipe 111 and the first circulating water return pipe 301. Likewise, heat exchange process of the heat exchange apparatus 200 operating in the malfunctioning state is carried out in the same way as that of the heat exchange apparatus 100 of Embodiment 1 operating in the malfunctioning state and is not described in detail again.

Operation of the normally closed solenoid valve 2011, 2021 and normally open solenoid valves 2012, 2022 may be controlled by an external controller (not shown), which is able to open the normally closed solenoid valves 2021, 2011 while closing the normally open solenoid valve 2022, 2012. The controller may be a conventional logic controller, such as a PLC controller. Based on the disclosure of the present application, those skilled in the art would recognize how to control the solenoid valves with a controller.

In particular, when the heat exchange apparatus 200 is operating in a normal state, the controller accordingly operates in a normal state. Therefore, the controller opens the normally closed solenoid valve 2021 of the second switcher 202 and the normally closed solenoid valve 2011 of the first switcher 201 and simultaneously closes the normally open solenoid valve 2022 of the second switcher 202 and the normally open solenoid valve 2012 of the first switcher 201. At this time, the cooling water inlet pipe 110 is disconnected from the reaction chamber 107, while the heat exchanger 108 is connected to the reaction chamber 107. Moreover, the cooling water outlet pipe 111 is disconnected from the reaction chamber 107, while the water tank 101 is connected to the reaction chamber 107. In this case, heat exchange process of the heat exchange apparatus 200 is carried out in the same way as that of the heat exchange apparatus 100 of Embodiment 1 operating in the normal state and is thus not described in detail again.

In the malfunctioning state of the heat exchange apparatus 200, the controller is accordingly in a malfunctioning state. With the controller being powered off due to malfunction, each of the normally closed solenoid valve 2021 of the second switcher 202 and the normally closed solenoid valve 2011 of the first switcher 201 closes, and simultaneously, each of the normally open solenoid valve 2022 of the second switcher 202 and the normally open solenoid valve 2012 of the first switcher 201 opens. At this time, the normally closed solenoid valve 2011 of the first switcher 201 is opened to disconnect the first circulating water outlet pipe 301 and the water tank 101, and the normally open solenoid valve 2012 of the first switcher 201 is opened to connect the cooling water inlet pipe 110 and the second circulating water outlet pipe 302. Moreover, the open normally closed solenoid valve 2021 of the second switcher 202 is opened to disconnect the second circulating water return pipe 402 and the heat exchanger 108, and the normally open solenoid valve 2022 of the second switcher 202 is opened to connect the cooling water outlet pipe 111 and the first circulating water return pipe 301. Likewise, heat exchange process of the heat exchange apparatus 200 operating in the malfunctioning state is carried out in the same way as that of the heat exchange apparatus 100 of Embodiment 1 operating in the malfunctioning state and is not described in detail again.

Reference can be made to Embodiment 1 for details in any feature that is not mentioned in Embodiment 2, and a further description thereof is omitted herein.

### Embodiment 3

FIG. 5 is a structural schematic of a heat exchange apparatus 200 according to embodiment 3 of the present application, which is connected to a reaction chamber 107. The heat exchange apparatus 200 includes a heat exchanger 108, a water tank 101, a cooling water inlet pipe 110, a cooling water outlet pipe 111, a circulating water outlet pipe 30, a circulating water return pipe 40, a first switcher 201 and a second switcher 202. The cooling water inlet pipe 110 and cooling water outlet pipe 111 are both connected to the heat exchanger 108, and cooling water is designed to flow through the cooling water inlet pipe 110 into the heat exchanger 108, where it undergoes a heat exchange process, and then flows out through the cooling water outlet pipe 111. The heat exchanger 108, water tank 101, circulating water outlet pipe 30, reaction chamber 107 and circulating water return pipe 40 are sequentially connected in series to form a loop.

This embodiment differs from Embodiment 2 in that, the first switcher 201 includes one normally closed solenoid valve 2012 and one normally open solenoid valve 2011, with the second switcher 202 including one normally closed solenoid valve 2022, one normally open solenoid valve 2021 and an external or internal controller.

In particular, when the heat exchange apparatus 200 is operating in a normal state, all the four solenoid valves are not powered on. That is, the normally closed solenoid valves 2012, 2022 are closed, and the normally open solenoid valves 2011, 2021 are open. In a malfunctioning state of the heat exchange apparatus 200, the controller instructs to power on the normally closed solenoid valves 2012, 2022 and the normally open solenoid valve 2011, 2021, thus opening the normally closed solenoid valves 2012, 2022. Reference can be made to Embodiment 2 for more details in operating state of other structures and operating principle. Therefore, the switch of the cooling channels is realized.

Based on the heat exchange apparatus provided in above embodiments, there is also provided a chemical vapour deposition device including the heat exchange apparatus and the chemical vapour deposition apparatus. The chemical vapour deposition apparatus includes a reaction chamber for accommodating a chemical vapour deposition process. Since the chemical vapour deposition device incorporates the heat exchange apparatus of the above embodiments, it thus has the beneficial effects brought in by the heat exchange apparatus and reference can be made to the above embodiments.

In summary, in the heat exchange apparatus, and heat exchange method thereof and vapour deposition device provided in the present application, the heat exchange apparatus includes a heat exchanger, a water tank, a cooling water inlet pipe, a cooling water outlet pipe, a circulating water outlet pipe, a circulating water return pipe, a first switcher and a second switcher. The cooling water inlet pipe and cooling water outlet pipe are both connected to the heat exchanger, and the heat exchanger, water tank, circulating water outlet pipe, an object to be cooled (e.g., a reaction chamber in the vapour deposition device) and circulating water return pipe are sequentially connected in series to form a loop. The first switcher is disposed between the cooling water inlet pipe and circulating water outlet pipe and the second switcher is arranged between the cooling water outlet pipe and circulating water outlet pipe.

When the heat exchange apparatus operates in a normal state, the first switcher connects the water tank and the object to be cooled while disconnecting the cooling water inlet pipe and the object to be cooled, and the second switcher connects the cooling water outlet pipe and the heat exchanger while disconnecting the cooling water outlet pipe and the object to be cooled. In this way, the water tank and heat exchanger that are serially connected to the object to be cooled are able to supply the object to be cooled with circulating water for cooling.

When the heat exchange apparatus malfunctions, the first switcher disconnects the water tank and the object to be cooled while connecting the cooling water inlet pipe and the object to be cooled. At the same time, the second switcher disconnects the cooling water outlet pipe and the heat exchanger while connecting the cooling water outlet pipe and the object to be cooled. In this way, the cooling water inlet pipe and cooling water outlet pipe that are serially connected to the object to be cooled are able to supply the object to be cooled with cooling water for cooling. Thus, effective cooling of the object to be cooled, in particular, the reaction chamber of the vapour deposition apparatus can be ensured at any situation, and thus the normal manufacturing can be proved. The vapour deposition apparatus may be either a vapour deposition device or a physical vapour deposition device, and the object to be cooled may be a structure of other apparatus that needs to be cooled.

The embodiments presented above are merely several preferred examples and are in no way meant to limit the present application. It is intended that any modifications such as equivalent alternatives or variations made to the subject matter or features thereof disclosed herein made by any person of ordinary skill in the art based on the above teachings without departing from the scope of the present application are also considered to fall within the scope of the present application.

1. A heat exchange apparatus, configured to cool an object to be cooled and comprising a heat exchanger, a cooling water channel, a circulating water channel and a switcher, wherein the cooling water channel is configured for heat exchange between cooling water and the heat exchanger, the circulating water channel configured to control a temperature of the object to be cooled, the switcher configured to disconnect the circulating water channel and the object to be cooled while connecting the cooling water channel and the object to be cooled.

2. The heat exchange apparatus of claim 1, wherein the cooling water channel comprises a cooling water inlet pipe and a cooling water outlet pipe that are connected to the heat exchanger, wherein the circulating water channel comprises a circulating water outlet pipe and a circulating water return pipe, and wherein the heat exchanger, the circulating water outlet pipe, the object to be cooled and the circulating water return pipe are connected in series to form a loop.

3. The heat exchange apparatus of claim 2, wherein the switcher comprises a first switcher and a second switcher, and the first switcher is disposed between the cooling water inlet pipe and the circulating water outlet pipe and configured to disconnect part of the circulating water outlet pipe and the object to be cooled while connecting the cooling water inlet pipe and the object to be cooled, and
wherein the second switcher is disposed between the cooling water outlet pipe and the circulating water return pipe and configured to disconnect the cooling water outlet pipe and the heat exchanger while connecting the cooling water outlet pipe and the object to be cooled.

4. The heat exchange apparatus of claim 3, wherein each of the first switcher and the second switcher is a three-way valve.

5. The heat exchange apparatus of claim 4, wherein the circulating water return pipe comprises a first circulating water return pipe and a second circulating water return pipe, the circulating water outlet pipe comprising a first circulating water outlet pipe and a second circulating water outlet pipe,
wherein a first end of the first circulating water outlet pipe is connected to the heat exchanger with a second end of the first circulating water outlet pipe being connected to the first switcher, wherein a first end of the second circulating water outlet pipe is connected to the first switcher with a second end of the second circulating water outlet pipe being connected to the object to be cooled, and the cooling water inlet pipe is connected to the first switcher via a first by-pass, and
wherein a first end of the first circulating water return pipe is connected to the second switcher with a second end of the first circulating water return pipe being connected to the object to be cooled, wherein a first end of the second circulating water return pipe is connected to the heat exchanger with a second end of the second circulating water return pipe being connected to the second switcher, and the cooling water outlet pipe is connected to the second switcher via a second by-pass.

6. The heat exchange apparatus of claim 4, wherein the three-way valve is a pneumatically-controlled three-way valve.

7. The heat exchange apparatus of claim 6, wherein the pneumatic control three-way valve is provided with a delivery passageway for allowing passage of compressed air, wherein arrangements of a pressure gauge and a pressure alarm into the delivery passageway are provided, wherein the pressure gauge is configured to measure a pressure of the compressed air and the pressure alarm is configured to give an alarm once the pressure of the compressed air drops below a preset value.

8. The heat exchange apparatus of claim 3, wherein the first switcher comprises a first normally closed solenoid valve and a first normally open solenoid valve, and the second switcher comprises a second normally closed solenoid valve and a second normally open solenoid valve.

9. The heat exchange apparatus of claim 8, wherein the cooling water inlet pipe is connected to the circulating water outlet pipe via a first by-pass, and the first normally open solenoid valve is disposed in the first by-pass with the circulating water outlet pipe being provided with the first normally closed solenoid valve, and wherein the cooling water outlet pipe is connected to the circulating water return pipe via a second by-pass, and the second normally open solenoid valve is disposed in the second by-pass with the circulating water return pipe being provided with the second normally closed solenoid valve.

10. The heat exchange apparatus of claim 8, wherein the cooling water inlet pipe is connected to the circulating water outlet pipe via a first by-pass, and the first normally closed solenoid valve is disposed in the first by-pass with the circulating water outlet pipe being provided with the first normally open solenoid valve, and wherein the cooling water outlet pipe is connected to the circulating water return pipe via a second by-pass, and the second normally closed solenoid valve is disposed in the second by-pass with the circulating water return pipe being provided with the second normally open solenoid valve.

11. The heat exchange apparatus of claim 9, further comprising a controller for controlling a power on or power off of the first and second normally closed solenoid valves and the first and second normally open solenoid valves.

12. The heat exchange apparatus of claim 3, wherein one or more of a temperature sensor, a pressure sensor and a flow meter are disposed in the circulating water channel.

13. The heat exchange apparatus of claim 3, wherein the object to be cooled is a process chamber.

14. A heat exchange method of the heat exchange apparatus as defined in claim 3, comprising:
disconnecting, by a first switcher, part of a circulating water outlet pipe and an object to be cooled while connecting a cooling water inlet pipe and the object to be cooled, so that cooling water flows into the object to be cooled after successively flowing through the cooling water inlet pipe and another part of the circulating water outlet pipe; and
disconnecting, by a second switcher, a heat exchanger and the object to be cooled while connecting a cooling water outlet pipe and the object to be cooled, so that the cooling water flowing out of the object to be cooled successively flows through a circulating water return pipe and the cooling water outlet pipe to accomplish heat exchange between the cooling water and the object to be cooled.

15. The heat exchange method of claim 14, wherein each of the first switcher and the second switcher is a three-way valve, and wherein connecting each of the cooling water inlet pipe and the cooling water outlet pipe to the object to be cooled comprises:
controlling, by a pneumatic actuating unit, the first switcher to disconnect the circulating water channel and the object to be cooled while connecting the cooling water inlet pipe and the object to be cooled; and
controlling, by the pneumatic actuating unit, the second switcher to disconnect the heat exchanger and the object to be cooled while connecting the cooling water outlet pipe and the object to be cooled.

16. The heat exchange method of claim 14, wherein the first switcher comprises a first normally closed solenoid valve and a first normally open solenoid valve, wherein the second switcher comprises a second normally closed solenoid valve and a second normally open solenoid valve, and wherein connecting each of the cooling water inlet pipe and the cooling water outlet pipe to the object to be cooled comprises:
closing the first normally open solenoid valve and the second normally open solenoid valve to connect the object to be cooled to each of the cooling water inlet pipe and the cooling water outlet pipe; and
opening the first normally closed solenoid valve and the second normally closed solenoid valve to disconnect the object to be cooled from each of the circulating water channel and the heat exchanger.

17. A vapour deposition device, comprising a heat exchange apparatus as defined in claim 1, wherein the heat exchange apparatus is configured to control a temperature of the vapour deposition device.
